(19) United States
(12) Patent Application Publication
(10) Pub. No.: US 2025/0038393 A1
(43) Pub. Date: Jan. 30, 2025

(54) DIRECTIONAL COUPLER AND RADIO FREQUENCY POWER AMPLIFIER SYSTEM BASED ON DIRECTIONAL COUPLER OUTPUT

(71) Applicant: SHENZHEN INSTITUTES OF ADVANCED TECHNOLOGY, Shenzhen (CN)

(72) Inventors: Hairong ZHENG, Shenzhen (CN); Xinwei RONG, Shenzhen (CN); Ye LI, Shenzhen (CN); Jiasheng WANG, Shenzhen (CN); Jifeng CHEN, Shenzhen (CN); Xing YANG, Shenzhen (CN)

(73) Assignee: SHENZHEN INSTITUTES OF ADVANCED TECHNOLOGY, Shenzhen (CN)

(21) Appl. No.: 18/911,015

(22) Filed: Oct. 9, 2024

Related U.S. Application Data
(63) Continuation of application No. PCT/CN2022/133930, filed on Nov. 24, 2022.

(51) Int. Cl. H01P 5/18; G01R 23/16

(52) U.S. Cl. CPC H01P 5/187; G01R 23/16

(57) ABSTRACT

The invention relates to a directional coupler, coupling high power and low power is used to replace existing two high-power directional couplers, thus reducing the cost and reducing the insertion loss of high-power radio frequency channels. The directional coupler cooperates with a control conditioning board, a splitter, a multi-path radio frequency power amplifier and a combiner to form the radio frequency power amplifier system, and the system is connected to a spectrometer; on one hand, by using a standard signal output by the spectrometer and a feedback signal of the directional coupler, nonlinearity caused by the power amplifier is corrected to achieve magnet-free linear radio frequency power amplification and anomaly protection; and on the other hand, the spectrometer can be used for monitoring the output power of the directional coupler and monitoring antenna matching, so as to provide dual protection for the radio frequency power amplifier system.

### TECHNICAL FIELD

The present invention relates to the field of radio frequency power amplifiers for medical magnetic resonance imaging, in particular to a directional coupler and a radio frequency power amplifier system based on a directional coupler output.

### BACKGROUND

In a magnetic resonance imaging system, a radio frequency power amplifier is a common device, and a radio frequency power output by the radio frequency power amplifier is generally between 5 KW and 35 KW, such that the radio frequency power amplifier is referred to as a high-power amplifier. The radio frequency power amplifier is generally connected to a radio frequency coil for amplifying an input radio frequency signal and outputting the amplified signal to the radio frequency coil. The output of the radio frequency power amplifier is required to be linear, that is, for different radio frequency signal powers, the radio frequency power amplification capability is consistent, with the same amplitude amplification factor and the same output phase. Therefore, it is necessary to add a control part to adjust the amplitude amplification factor and the output phase of the radio frequency power amplifier to achieve gain constancy and phase constancy, which is referred to as nonlinearity correction.

In general nonlinearity correction, a dual directional coupler is added to an output end, and a coupling channel is used for sampling output signals, which are attenuated by an attenuator, such that the signals have reduced power and enter the control part, thus achieving the control of amplitude and phase. The isolation port of the dual directional coupler monitors a matching condition between the radio frequency power and coils, and is used for detecting a voltage standing wave ratio at the output end port for protection in abnormal situations.

According to “Design of Unmagnetized 5T Magnetic Resonance Radio Frequency Power Amplifier”, Chinese Journal of Magnetic Resonance, June 2022, No. 2, Vol. 39, P163-173, the output power is 2 KW, a single dual directional coupler is used, the coupling port is reduced to improve directivity, the output of the coupling port is of dozens of watts, but a large attenuator (40 dB) is required to reduce the output power, thus achieving a power of milliwatts into the control processing board; nonlinearity correction is carried out, and the other port is used for monitoring the matching between the output and the antenna. The attenuator of the coupling channel not only attenuates the signal power, but also reduces the signal-to-noise ratio of the signal, especially at a low-power input where the signal-to-noise ratio is poor, which affects the correction of a modulation signal. According to the method, another high-power directional coupler is required to be added for output, and the outputs of the coupling end and the isolation end are sent to the spectrometer for monitoring the matching between the output power and the antenna, such that the cost is increased.

The output of the radio frequency signal generated by the spectrometer is related to the number of bits of the DAC. In a working bandwidth range, the signal-to-noise ratio (SNR) can be theoretically calculated by using the following formula:

$$S N R = 6 \text{.02} N + 176 dB$$

In the formula: n is the number of bits of the DAC, and the maximum signal-to-noise ratio is 74 dB for a 12-bit DAC.

A general broadband high-speed DAC has 12 bits, the signal-to-noise ratio of the output signal is 74 dB, which is very good. However, after signal modulation, the main carrier part occupies the main part of energy and has a high signal-to-noise ratio, while other sideband signals are generally lower than the carrier signal, and some sideband signals can reach-35 dBc. The signals output by the spectrometer are typically required to have a dynamic range of 40 dB, for example, having a sideband signal with an amplitude in the near band-35 dBc lower than that of the main peak signal. In this way, the signal-to-noise ratio of the main signal is 74 dB, the signal-to-noise ratio of the sideband signal is reduced to 39 dB; the signal-to-noise ratio of the main signal is reduced to 34 dB by the directional coupler and the fixed 40 dB attenuator, and the signal-to-noise ratio of the nearby sideband signal is reduced to −1 dB, which is substantially drowned out in noise, which greatly affects the processing of the modulation signal. This is the reason why information such as signal amplitude, phase, and modulation needs to be extracted from an attenuator connected behind the directional coupler, which has a requirement for the signal-to-noise ratio, and attenuation cannot be too large. If only the amplitude of the peak is extracted, the requirement for the signal-to-noise ratio is low, which is the reason why an attenuator is used for connection in a common power detection.

The spectrometer monitors the output of the radio frequency power amplifier, and a high-power dual directional coupler needs to be further added, which is connected to the antenna port and the output port of the first directional coupler. After the coupling end and the isolation end of the dual directional coupler are connected to the attenuator, the power of the output can be reduced and the output can be sent to the spectrometer for monitoring. The addition of the second high-power directional coupler increases the complexity and cost.

The signal control conditioning board is used for carrying out nonlinearity correction on a signal fed back by the directional coupler. The signal is generally simplified as an ideal signal in theoretical analysis, and the signal-to-noise ratio is ignored. However, in practice, there is a requirement for the signal-to-noise ratio of the input signal. When the signal-to-noise ratio is poor, especially when the input signal is weak, the noise superimposed in the control signal is likely to cause a great fluctuation. As a result, when the radio frequency power amplifier is within the linearity range and the input power is low, the noise fluctuation interferes with the amplitude and the phase.

The output of the coupling channel of the dual directional coupler is connected to the large attenuator, which not only attenuates the signal power, but also reduces the signal-to-noise ratio of the signal. In addition, the cost is increased by using 2 high-power dual directional couplers.

It is a problem to be solved to use a high-power low-cost directional coupler to achieve multi-port output, where a master coupling port achieves great attenuation and a good signal-to-noise ratio.

### SUMMARY

In view of the prior art described above, the present invention intends to provide a multi-port directional coupler, which makes improvements to the existing four-port directional coupler by adding ports 5 and 6, such that the multi-port directional coupler can implement functions of a second high-power directional coupler in two high-power directional couplers that are required at present. Furthermore, a dual directional coupler is formed by cascading the multi-port directional coupler and a low-power directional coupler so as to replace the existing two high-power directional couplers, thereby reducing the cost and reducing the insertion loss of high-power radio frequency channels. The described multi-port dual directional coupler cooperates with a control conditioning board, a splitter, a multi-path radio frequency power amplifier, and a combiner to form a radio frequency power amplifier system, and the system is connected to a spectrometer; on one hand, nonlinearity correction is carried out with reference to a standard signal output by the spectrometer and a feedback signal with power amplification to achieve nonmagnetic linear radio frequency power amplification, so as to obtain linear radio frequency power suitable for magnetic resonance imaging systems; and on the other hand, the spectrometer can be used for monitoring the output power of the multi-port directional coupler and monitoring antenna matching, so as to achieve a secondary protection function for protecting the radio frequency power amplifier system. In order to achieve the above object, the present invention provides the following technical solutions.

In a first aspect, the present invention provides a multi-port directional coupler. The multi-port directional coupler uses a PCB microstrip circuit and is provided with 6 ports, including a port 1, a port 2, a port 3A, a port 4, a port 5, and a port 6, where the port 1 is an input of the multi-port directional coupler, and the port 2 is an output of the multi-port directional coupler; the port 3A is a master coupling port with a given directivity value; the port 4 is a master isolation port with a given directivity value; the port 5 is a slave coupling port for detecting a transmitting power of the port 1; the port 6 is a slave isolation port for detecting a reflecting power of the port 2; and the ports 5 and 6 are in mirror symmetry with the ports 3A and 4.

The above technical solution provides a six-port directional coupler, which is a multi-port directional coupler with a given directivity value. Symmetrical slave coupling port 5 and slave isolation port 6 are formed through mirror image arrangement, which can function in place of a coupling port and an isolation port of a high-power directional coupler.

As an improvement to the above technical solution, the multi-port directional coupler is provided with 3 layers of PCBs, the third layer is a bottom layer of PCB as a reference ground, the port 1 to the port 2 are located at a top layer of PCB, and the ports 5 and 6 and the ports 3A and 4 are located at the second layer of PCB, so as to improve insulation of a channel from the port 1 to the port 2, and prevent from sparking due to high-power output.

As an embodiment of the above technical solution, the port 3A of the multi-port directional coupler improves a coupling degree by being connected to a slave directional coupler after being connected to a first attenuator; and a peak input power of the slave directional coupler is less than 100 watts, and a coupling port is used as an output port 3B. In such an embodiment, when the multi-port directional coupler works, the peak power can be greater than or equal to 1 kilowatt, such that two-stage cascading of the coupling end of the high-power directional coupler and the low-power directional coupler is achieved, which achieves a great attenuation in a key signal channel for a coupling signal channel, which not only meets the input power requirements of a control part, but also improves a signal-to-noise ratio of the input signal, especially for the low-power sideband input of the modulation signal.

In another embodiment of the above technical solution, the port 4, the port 5, or the port 6 is able to improve a signal-to-noise ratio by being connected to a slave directional coupler after being connected to a second attenuator, and a peak input power of the slave directional coupler is less than 100 watts, and a coupling port is used as an output port.

In a second aspect, the present invention provides a radio frequency power amplifier system based on a directional coupler output, where the system includes a control conditioning board, a pre-amplifier, a driving amplifier, a splitter, a radio frequency transistor amplifier, a combiner, and a dual directional coupler; the dual directional coupler includes a multi-port directional coupler and a slave directional coupler, and a peak input power of the slave directional coupler is less than 100 watts; the multi-port directional coupler uses a PCB microstrip circuit and is a master directional coupler, and is provided with 6 ports, including a port 1, a port 2, a port 3A, a port 4, a port 5, and a port 6, where the port 1 is an input of the multi-port directional coupler, the port 2 is an output of the multi-port directional coupler, and the port 2 is connected to an antenna port; the port 3A is a master coupling port with a given directivity value, and an attenuator is formed at the port 3A by adding a resistor for fine adjustment and is then connected to the slave directional coupler; the port 4 is a master isolation port with a given directivity value for monitoring a radio frequency output and matching of an antenna; the port 5 is a slave coupling port for outputting the attenuated power relative to the port 1; the port 6 is a slave isolation port for outputting the attenuated power relative to the port 2; and signals output by the ports 5 and 6 are attenuated and then sent to a spectrometer. In an embodiment, the attenuator used for attenuation is a x-type or T-type attenuator formed by chip resistors, or a coaxial attenuator; the ports 5 and 6 are in mirror symmetry with the ports 3A and 4; in the slave directional coupler, a port 3A1 is used as an input port, a coupling port is used as an output coupling port 3B, which is connected to the control conditioning board to form closed-loop correction of a radio frequency link, and the other 2 ports are connected to matched loads; in the system, nonlinearity correction is carried out on a standard signal RF_IN1 generated by the spectrometer by using a feedback signal of the port 3B to form a signal RF_IN2; the signal RF_IN2 is sent to the pre-amplifier for preliminary radio frequency power amplification to form a signal RF_IN3; the signal RF_IN3 is sent to the driving amplifier for further radio frequency power amplification to form a signal RF_IN4; the signal RF_IN4 is sent to a power distributor for power distribution, then to the radio frequency transistor power amplifier, and then to the power combiner to be combined into a signal RF_C1, the signal RF_C1 is output to the multi-port directional coupler as a total power to generate a signal RF_C2, and the signal RF_C2 is sent to a radio frequency antenna of magnetic resonance.

In the above technical solution, the multi-port directional coupler cooperates with the radio frequency power amplifier, the combiner, and the control conditioning part to achieve the nonmagnetic linear radio frequency power amplifier. The spectrometer is connected to achieve monitoring of the radio frequency output power and monitoring of matching of the antenna. As the two-stage cascading of the coupling end of the high-power directional coupler and the low-power directional coupler is adopted in the multi-port directional coupler, the cost is reduced for the coupling signal channel. The above multi-port directional coupler achieves the great attenuation in the key signal channel, meets the input power requirements of the control part, and improves the signal-to-noise ratio of the input signal, especially for the low-power sideband input of the modulation signal. Compared with two high-power directional couplers, the insertion loss of the radio frequency channel signal of one high-power directional coupler is smaller.

As an improvement to the above technical solution, the multi-port directional coupler is provided with 3 layers of PCBs, the third layer is a bottom layer as a reference ground, the port 1 to the port 2 are located at a top layer of PCB, and the ports 5 and 6 and the ports 3A and 4 are located at the second layer of PCB, so as to improve insulation of a channel from the port 1 to the port 2.

In the above technical solution, the power distributor performs equal-power and same-phase power distribution, M channels are formed by N powers of 2, each channel is sent to the radio frequency transistor power amplifier, the M radio frequency transistor power amplifiers enter the corresponding power combiners, and the power combiners perform equal-power and same-phase power combination.

In the above technical solution, the radio frequency transistor power amplifier receives a channel signal distributed by the power distributor, and sends the channel signal to a Balun formed by PCB microstrip lines to form a signal with equal power and a phase difference of 180 degrees; and an input of the transistor amplifier is matched according to impedance of an optimal input power to achieve balanced power amplification, then subjected to balanced matching output according to impedance of an optimal output power, which is consistent with impedance of an output Balun, and finally converted into a single-ended signal output by the output Balun and sent to the corresponding power combiner.

In a third aspect, the present invention provides a radio frequency power linearization method for a magnetic resonance imaging system. The method includes:
cascading a multi-port directional coupler and a slave directional coupler in two stages, where a peak input power of the slave directional coupler is less than 100 watts; the multi-port directional coupler uses a PCB microstrip circuit and is provided with 6 ports, including a port 1, a port 2, a port 3A, a port 4, a port 5, and a port 6, where the port 1 is an input of the multi-port directional coupler, the port 2 is an output of the multi-port directional coupler, and the port 2 is connected to an antenna port; the port 3A is a master coupling port with a given directivity value, and an attenuator is formed at the port 3A by adding a resistor for fine adjustment and is then connected to the slave directional coupler; the port 4 is a master isolation port with a given directivity value for outputting an attenuated power relative to the port 1 and a reflecting power of the port 2, monitoring a radio frequency output and matching of an antenna, and performing primary anomaly protection; the port 5 is a slave coupling port for outputting the attenuated power relative to the port 1; the port 6 is a slave isolation port for outputting the attenuated power relative to the port 1 and the reflecting power of the port 2; signals output by the ports 5 and 6 are attenuated and then sent to a spectrometer; and the ports 5 and 6 are in mirror symmetry with the ports 3A and 4;
in the slave directional coupler, a port 3A1 is used as an input port, a coupling port is used as an output coupling port 3B, which is connected to the control conditioning board to form closed-loop correction of a radio frequency link, and the other 2 ports are connected to matched loads;
nonlinearity correction is carried out on a standard signal RF_IN1 generated by the spectrometer by using a signal output by the port 3B as a feedback signal of the multi-port directional coupler, where one embodiment for the nonlinearity correction adopts a linear correction method of analog negative feedback, and a signal formed after the correction is RF_IN2;
the signal RF_IN2 is sent to the pre-amplifier for preliminary radio frequency power amplification to form a signal RF_IN3;
the signal RF_IN3 is sent to the driving amplifier for further radio frequency power amplification to form a signal RF_IN4; and
the signal RF_IN4 enters a power distributor for power distribution, then to the radio frequency transistor power amplifier, and then to the power combiner to be combined into a signal RF_C1, the signal RF_C1 is output to the directional coupler as a total power to generate a signal RF_C2, and the signal RF_C2 is sent to a radio frequency antenna of magnetic resonance. The closed-loop correction of the signal output by the port 3B of the directional coupler and the signal RF_IN1 ensures linearity of the finally output RF_C2.

### BRIEF DESCRIPTION OF DRAWINGS

In order to more clearly explain the technical solutions in the embodiments of the present application, the following will briefly introduce the drawings needed in the description of the embodiments. Obviously, the drawings in the following description are only some embodiments of the present application. For those of ordinary skill in the art, other drawings can be obtained according to these drawings without any creative effort.

FIG. 1 is a schematic diagram of a six-port directional coupler according to an embodiment;

FIG. 2 is a schematic diagram of a radio frequency power amplifier system based on a six-port directional coupler according to an embodiment;

FIG. 3 is a schematic structural diagram of a transistor pair balanced amplifier of a power amplifier 1 according to an embodiment;

FIG. 4 is a schematic diagram of an open-loop test with an output of 8 KW of a radio frequency power amplifier system based on a directional coupler according to an embodiment;

FIG. 5 is a schematic diagram of a PCB board of a master directional coupler according to an embodiment;

FIG. 6 is a schematic diagram of a simulation structure of a slave directional coupler according to an embodiment;

FIG. 7 is a simulation of a coupling degree from 3A1 of a slave directional coupler to 3B according to an embodiment;

FIG. 8 is a simulation of an isolation degree from a port 1 to a port 4 of a master directional coupler;

FIG. 9 is a simulation of a coupling degree from a port 1 of a master directional coupler to a port 3B; and

FIG. 10 is an insertion loss from a port 1 to a port 2 of a master directional coupler.

### DETAILED DESCRIPTION OF THE EMBODIMENTS

The technical solutions in embodiments of the present application will be described clearly and completely with reference to the drawings in the embodiments of the present application, and it is obvious that the described embodiments are merely some embodiments of the present application, and not all embodiments.

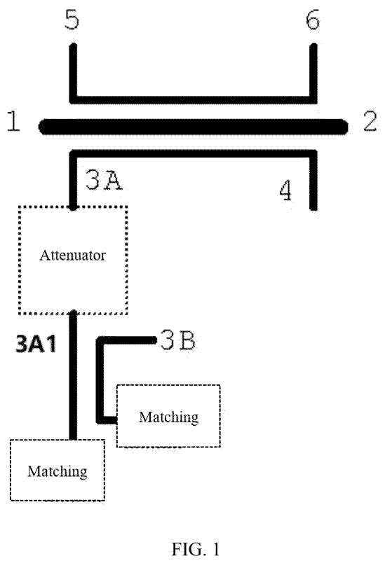

In an embodiment, a 5T nonmagnetic radio frequency power amplifier is used, with a frequency of 210.78 MHZ, a peak output P1 dB power of 8 KW (69 dBm), a saturation power of about 8.4 KW (69.25 dBm), a test duty cycle of 8%, an 8 millisecond (mS) pulse emission, and a period of 1 second(S). A multi-port dual directional coupler with a given directivity value as shown in FIG. 1 is employed, which uses a PCB microstrip circuit. Through two-stage cascading of a coupling end of a high-power directional coupler and a low-power directional coupler, which achieves a great attenuation in a key signal channel for a coupling signal channel, the coupler not only meets input power requirements of a control part, but also improves a signal-to-noise ratio of an input signal, especially for a low-power sideband input of a modulation signal.

The high-power directional coupler is a multi-port directional coupler and serves as a master directional coupler, and the low-power directional coupler is a slave directional coupler. It should be noted that in some embodiments, a peak power that is greater than or equal to 1 KW is considered as a high power. In other embodiments, a peak power between 5 KW and 35 KW is considered as a high power. In yet other embodiments, the high power is defined as a peak of a number of kilowatts, such as 10 KW or 20 KW. In some embodiments, the low power is defined as dozens of watts or less, such as 10 W or less. In other embodiments, a peak power less than 100 W is considered as a low power.

In the design of the directional coupler, for a coupling degree and an isolation degree:

directivity=isolation degree−coupling degree

The coupling degree and the isolation degree effect each other, and the desired directivity is better than 15 dB to 20 dB.

Greater values of the coupling degree and the isolation degree are desirable, but they can only be compromised in engineering due to the PCB processing technology and mutual effects among multiple ports.

For the high-power directional coupler, satisfaction for power requirements and a low insertion loss are preferred, followed by the coupling degree, which is required to be 25 dB to 30 dB, and the isolation degree is required to be 45 dB to 50 dB.

For the low-power directional coupler, the coupling degree is required to be 25 dB to 30 dB.

In this way, in the designed multi-port directional coupler, after the master directional coupler and the slave directional coupler are cascaded by a 3 dB attenuator formed by resistors, the required coupling degree ranges from 55 dB to 60 dB from a port 1 to a port 3B, and the signal-to-noise ratio is only reduced by 3 dB, which meets a signal-to-noise ratio requirement of signal input of a control conditioning board. For other special requirements, if no attenuator is needed, the resistance value is selected to be 0 ohm to form straight-through, and the attenuation value is 0 dB. In FIG. 1, a port 1 is an input of the multi-port directional coupler, a port 2 is an output of the multi-port directional coupler, the port 1 and the port 2 have a low insertion loss in a working band, which is less than 0.1 dB, and a peak power of transmission pulses is 10 KW; and ports 3A and 4 are provided with given directivity values, the port 3A is a master coupling port with a given coupling degree, the port 4 is a master isolation port for outputting an attenuated power relative to the port 1 and a reflecting power of the port 2 and for monitoring a radio frequency output and matching of an antenna. Symmetrical slave coupling port 5 and slave isolation port 6 are further formed through mirror image arrangement. The port 5 is a slave coupling port for outputting the attenuated power relative to the port 1; and the port 6 is a slave isolation port for outputting the attenuated power relative to the port 1 and the reflecting power of the port 2. At the master coupling port 3A, a x-type or T-type 3 dB attenuator formed by resistors is added for fine adjustment. A x-type attenuator is used herein, with 300 ohms on both sides, 18 ohms in the middle, and a chip power resistor of 3 W. Then an input port 3A1 of the second-stage low-power directional coupler is connected, where the second-stage directional coupler only has the coupling port serving as the output coupling port 3B, and the other 2 ports are connected to matched loads.

For the radio frequency power amplifier system of 5T magnetic resonance, except the control conditioning board, the other parts are integrated on a PCB board. The PCB board has 6 layers and consists of the multi-port directional coupler and the whole power amplifier system, where the directional coupler is applied to 3 layers of the PCB board. Specifically, main parameters of the multi-port directional coupler include: a center frequency of 210.78 MHz, a Roger4350B panel, 3 layers of PCB, a thickness of 1.6 mm of the 3 layers of PCB, the third layer being a bottom layer as a reference ground, and a thickness of the first layer to the second layer being 0.29 mm. A line width from the port 1 to the port 2 is 3.5 mm, with characteristic impedance of 50 ohm and a length of 50 mm, and an 8.4 KW testing is normal at a top layer of PCB. A coupling section of the ports 3A and 4 has a line width of 2.8 mm and a length of 27.2 mm, and a distance between an orthographic projection to the top layer and the edge of the port 1 and the port 2 is 0.8 mm. The ports 5 and 6 and the ports 3A and 4 are located at the second layer, with an inner edge distance of 5.1 mm. The ports 5 and 6 and the ports 3A and 4 are located at the second layer of PCB, so as to improve insulation and prevent from arc sparking at a high power.

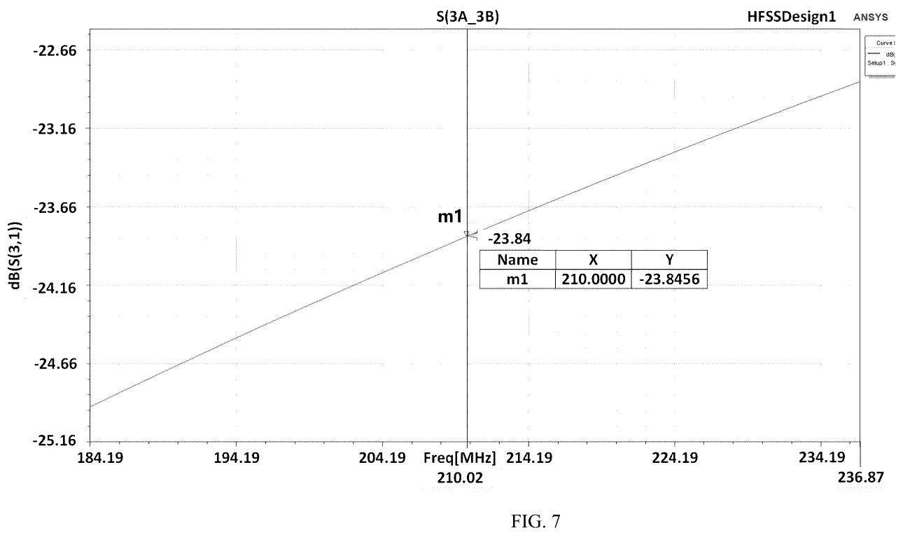

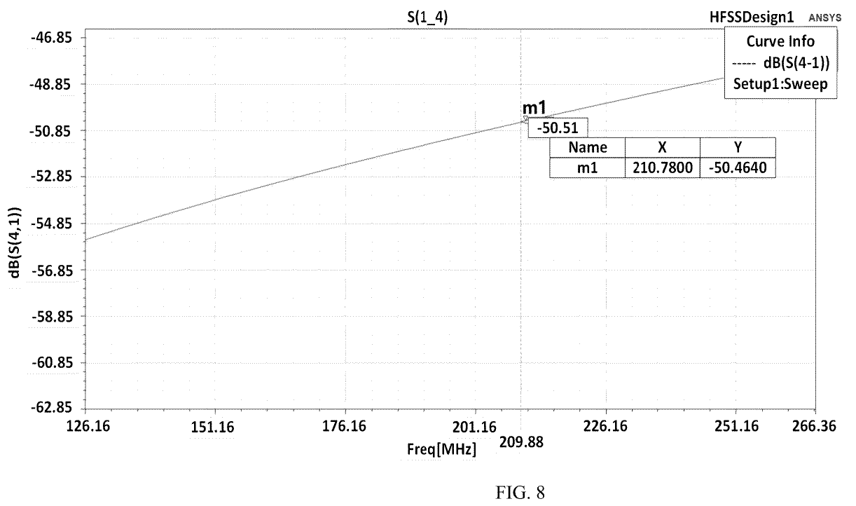

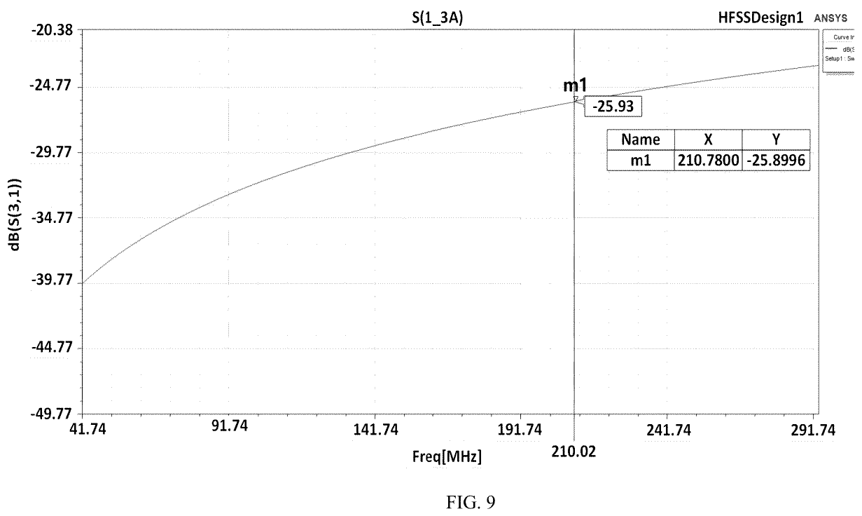

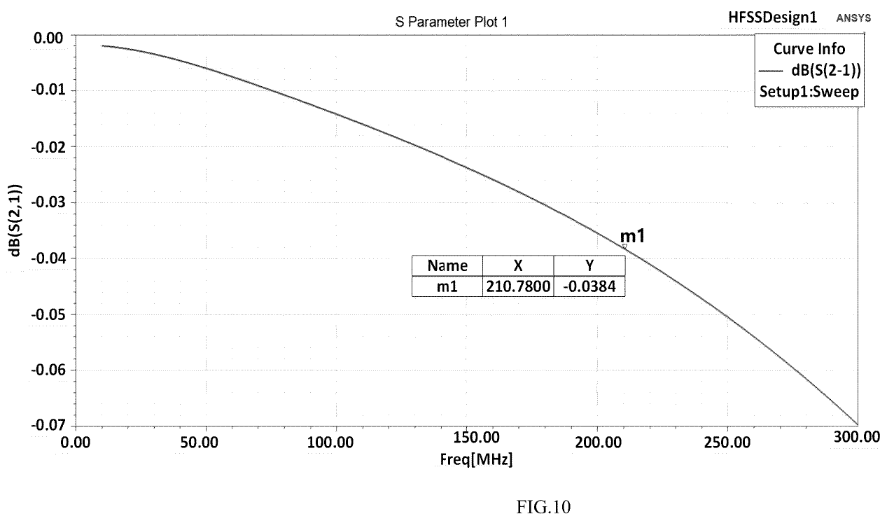

Referring to FIGS. 8, 9, and 10 for simulated parameters of the master directional coupler, the insertion loss from the port 1 to the port 2 is 0.04 dB, the coupling degree from the port 1 to the port 3A is 25.8 dB, and the isolation degree from the port 1 to the port 4 is 50.4 dB. Referring to FIG. 7, the coupling degree from the port 3A1 of the slave directional coupler to the port 3B is 23.8 dB. In this way, as the 3 dB resistance attenuator is connected to the master directional coupler, the coupling degree from the port 1 to the port 3B is (23.8 dB+3 dB+25.8 dB), which is equal to 52.6 dB, which does not reach the required coupling degree of 55 dB to 60 dB. The coupling degree of the slave directional coupler needs to be optimized, with a target of the coupling degree of 30 dB, and then PCB board verification is carried out.

Here, according to the desired port 3A, a second-stage auxiliary directional coupler is connected after the first attenuator is connected. From the port 1 to the coupling port 3B, after passing through 3A of the master directional coupler, the slave directional coupler outputs from the port 3B, which achieves high attenuation, thereby reducing the use of high-value attenuators, achieving a radio frequency signal output of about 0 dBm and ensuring an excellent output signal-to-noise ratio. From 3A to 3B, the coupling degree is improved, the attenuation of resistance is reduced, and the signal-to-noise ratio is improved. The attenuation value of the first attenuator is low, such as 3 db, which requires a good signal-to-noise ratio for an interface part. The other ports 4, 5, and 6, if there are special requirements for the signal-to-noise ratio, can also improve the signal-to-noise ratio in the same way by being connected to a slave directional coupler after being connected to a second attenuator. If there is no special requirement for the signal-to-noise ratio, the attenuation value of the attenuator connected behind is large, such as between 20 dB and 40 dB. The outputs from the three ports are used for power detection after passing through the attenuator, and the requirement for the signal-to-noise ratio is not strict. Depending on the power requirements of the output connection port, such as 0 dBm, an attenuator formed by resistors or another external attenuator is generally used for connection.

The port 3B is used for connecting to the control conditioning board and outputting a feedback signal for nonlinearity correction on a standard signal output by a spectrometer, and is further used for detecting the input power of the port 1. The port 2 is connected to an antenna port as a high-power output port. The port 4 is the master isolation port for outputting the attenuated power relative to the port 1 and the reflecting power of the port 2 into the control conditioning board, monitoring the output, and performing primary protection when the antenna is mismatched (for example, when a voltage standing wave ratio is 3) and turning off the input power of the power amplifier. For example, the port 5 is attenuated by about 30 dB relative to the port 1, and due to structural symmetry, the port 6 is attenuated by about 30 dB relative to the port 2. A peak pulse power of 69 dBm is input at the port 1, and is attenuated to 39 dBm at the port 5, then the power is attenuated by about 24 dB for fine adjustment as it passes through a x-type attenuator formed by 3 W chip resistors, then the power passes through a fixed 1 W attenuator of 15 dB, such that the power is reduced to about 0 dBm from 39 dBm, and then the power is sent to the spectrometer for monitoring the radio frequency transmitting power. The power at the port 6 is the power attenuated by the isolation degree of the port 1 plus the power reflected and coupled at the port 2. For example, if the input peak pulse power at the port 1 is 69 dBm and the isolation degree of the port 6 is 50 dB, the power at the port 6 coupled from the port 1 is 19 dBm (69 dBm-50 dB), which is about 79 mW; for example, when the port 2 is mismatched and half reflection occurs where half of the energy is reflected, which is 69 dBm-3 dB, which is equal to 66 dBm, the energy at the port 6 coupled from the port 2 is 66 dBm-30 dB, which is equal to 36 dBm, which is about 3981 mW. In this case, the total energy at the port 6 is 39.1 dBm (4060 mW), which is reduced to about 0.1 dBm after attenuation of 39 dB, and is then sent to the spectrometer for monitoring the matching state.

The port 5 is used for detecting the transmitting power of the port 1, and the port 6 is used for detecting the reflecting power of the port 2 and is connected to the spectrometer. Therefore, the function of a second high-power directional coupler is replaced. Generally, the spectrometer is connected for output power detection and matching state monitoring. When an abnormality occurs (for example, the voltage standing wave ratio is 5), the spectrometer stops the output power and performs secondary protection.

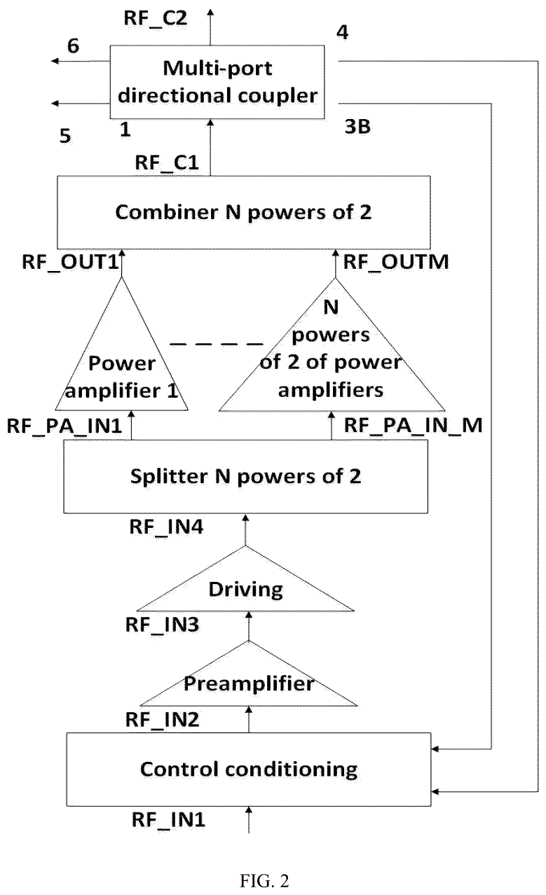

The radio frequency power amplifier system for magnetic resonance based on a multi-port directional coupler provides a radio frequency signal for magnetic resonance. As shown in FIG. 2, the spectrometer is used for monitoring the output of the radio frequency power amplifier and matching of the antenna. The standard signal RF_IN1 generated by the spectrometer is sent to the control conditioning board for nonlinearity correction in combination with the feedback signal of the directional coupler so as to form a signal RF_IN2. The signal RF_IN2 is sent to a pre-amplifier for preliminary radio frequency power amplification to form a signal RF_IN3, which is then sent to a driving amplifier for further radio frequency power amplification, and then sent to a power distributor, thereby achieving linear amplification.

The power distributor performs equal-power and same-phase power distribution, M channels are formed by N powers of 2, and the power amplified by a single power amplifier in each channel is the same. Each channel is sent to the radio frequency transistor power amplifier, the M radio frequency transistor power amplifiers enter the corresponding power combiners, and the power combiners perform equal-power and same-phase power combination. A combined signal RF_C1 is output as a total power, the total power is M times the power amplified by a single power amplifier, and finally the combined signal is sent to the six-port directional coupler, such that a signal RF_C2 is sent to a radio frequency antenna of magnetic resonance. By changing the number of channels M, the total power to be increased can be changed in a linear manner.

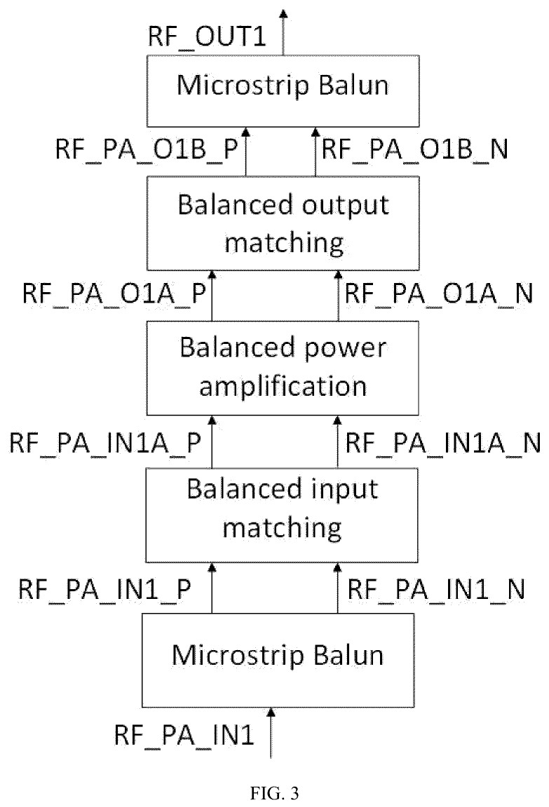

The M paths of radio frequency transistor power amplifiers are the same, and the first path is used herein for description. Referring to FIG. 3, a signal RF_PA_IN1 is sent to a Balun formed by PCB microstrip lines to form a signal with equal power and a phase difference of 180 degrees. The input of the transistor amplifier is subjected to balanced input matching, and is matched according to impedance of an optimal input power, such that the transmission of the maximum power is ensured while a stable working state is ensured without any self-excited oscillation; the signal after the balanced input matching processing is input into balanced power amplification and then output through balanced output matching. The output of the radio frequency transistor amplifier is subjected to balanced matching output according to impedance of an optimal power, where the output power is consistent with impedance of an output Balun; and finally converted into a single-ended signal RF_OUT1 output by the output Balun and sent to the power combiner. In this embodiment, the radio frequency high-power amplifier used in the single-channel power amplifier is a field-effect transistor of MRFX1K80N. When the central working frequency of the radio frequency pulse signal is 210.78 MHz, the working DC voltage is 75 V, the period is 100 mS, the pulse width is 200 uS, and when the peak input power of the radio frequency pulse signal is 14 W, the saturated peak output power of the radio frequency pulse signal is 2400 W. In this embodiment, four identical power amplification channels are used, and finally an 8 KW output is formed. A splitter is connected in series by two stages to form four output ports which are interfaced with four paths of power amplifier input channels. The combiner is connected in series by two stages to form four input ports which are interfaced with four paths of power amplifier output channels.

For the control conditioning board, the nonlinearity correction of the radio frequency power amplifier system is achieved based on the detection signal output by the port 3B of the directional coupler and the signal input by the spectrometer; the reflection of the port 2 is detected by using the port 4, which, after being attenuated, is input into the signal conditioning board for power detection to calculate the matching condition of the antenna. When the port 2 has not reflected ideal matching, the port 2 has no power coupling to the port 4, only the port 1 has coupling to the port 4, the coupling coefficient is equal to the isolation degree and is about 50 dB, and the output power of the port 4 is 69 dBm-50 dB, which is equal to 19 dBm; when the output of the port 2 is mismatched and the voltage standing wave ratio (VSWR) is 3, the output power of the port 2 is reflected by nearly 25%, the coupling of the port 4 to the port 2 is 30 dB, the port 2 has 8 KW×25%, which is equal to 2 KW (63 dBm), and the port 4 has 63 dBm-30 dB, which is equal to 33 dBm. Therefore, the output of the port 4 is changed from 19 dBm without reflection to 33 dBm caused by reflection, and is sent to a signal detection board for linear power detection after passing through a fixed attenuator, so as to determine the matching condition of the output of the port 2. When the VSWR is equal to 3, the output of the port 4 is 33 dBm, which is considered to be a serious mismatch, such that a signal processing board turns off the output of the radio frequency signal to protect the radio frequency power amplifier system, which is primary protection inherent to the power amplifier system.

In the above embodiment, by eliminating a high-power directional coupler, the insertion loss and cost of the total radio frequency output power are reduced. According to the present invention, the signal of the control conditioning board is input to the coupling end, such that the signal-to-noise ratio of the input signal is improved, thereby improving the linearity of the entire radio frequency power amplifier.

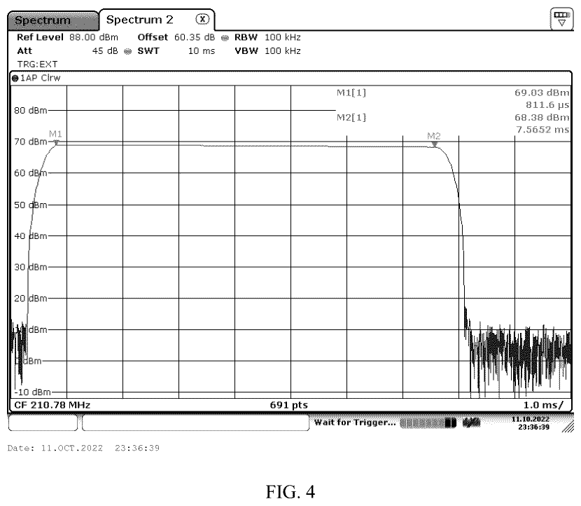

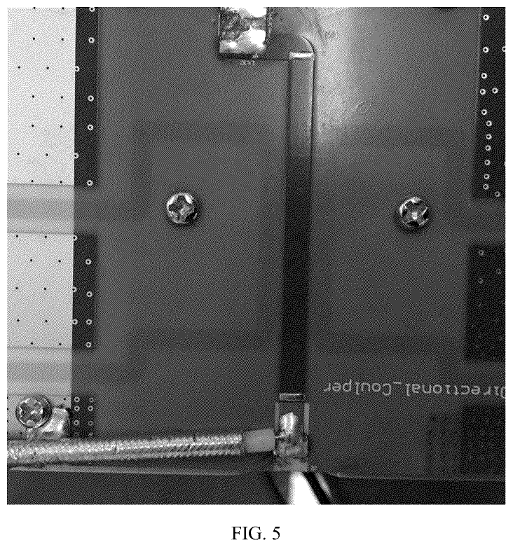

In another embodiment, the radio frequency power amplifier system based on a directional coupler is used for a 5T nonmagnetic radio frequency power amplifier, with a center frequency of 210.78 MHz and a P1dB output open-loop power of 8 KW, as shown in FIG. 4; the transistor pair uses MRFX1K80H of NXP, with a working voltage of 75 Vdc. The directional coupler uses Rogers4350B which is a PCB substrate, as shown in FIG. 5.

In data tested by using a vector network analyzer in a test of the master directional coupler, the insertion loss from the port 1 to the port 2 is 0.06 dB, the coupling degree of the port 3A to the port 1 is 32 dB, the isolation degree of the port 4 to the port 1 is 43 dB, the coupling degree of the port 5 to the port 1 is 32 dB, and the isolation degree of the port 6 to the port 1 is 43 dB. There are differences between the test data and the simulation. The isolation degree needs to be improved to 50 dB by adjustment based on the processing technology of the PCB.

The coupling degree of the port 3B of the slave directional coupler to the port 3A1 is 25 dB.

In the master directional coupler, the input is input into the port 1, and the directivity of the port 4 to the port 3A is (43-32) dB, which is equal to 9 dB, which does not reach the given target of 15 dB, such that a further improvement is needed. According to a difference analysis of the test results of the master directional coupler, due to the standard thickness parameter (0.254 mm) in factory processing and the PCB thickness (0.29 mm) designed of the top layer and the second layer, the difference of the thickness has resulted in the variations in the results, resulting in the failure to achieve the preset target of directivity. Therefore, other parameters are further finely adjusted based on the fixed standard thickness so as to improve the isolation degree, and further improve the directivity to a preset range of 15 dB to 20 dB.

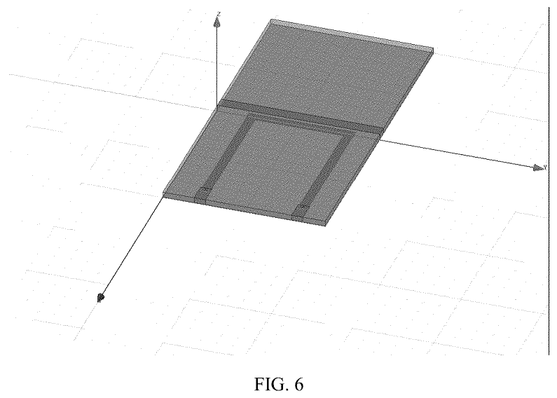

The coupling degree of the slave directional coupler is confirmed through simulation. A schematic diagram of the simulation structure is shown in FIG. 6, and a simulation result is shown in FIG. 7. The coupling degree from the port 3A1 to the port 3B is 23.8 dB. Next, the isolation degree is optimized to 30 dB, and the slave directional coupler is further processed for test verification. Then, the master directional coupler and the slave directional coupler are connected by using a 3 dB attenuator formed by resistors, and the isolation degree from the port 1 to the port 3B of the connected six-port directional coupler is tested to meet the coupling degree of 55 dB to 60 dB, and finally the two are integrated.

The cascaded directional coupler designed in this embodiment extracts a coupling signal of a high signal-to-noise ratio by using a nonlinearity correction method of analog negative feedback, thereby achieving the linear correction of the amplitude and phase of the output signal at the output port of the directional coupler. It should be noted that a similar directional coupler structure can also be used to extract a coupling signal of a high signal-to-noise ratio for carrying out nonlinearity correction. Both the nonlinearity correction methods fall within the protection scope of the present invention.

Although the embodiments of the present invention have been described above with reference to the accompanying drawings, the present invention is not limited to the above specific embodiments and application fields. Rather, the above specific embodiments are only illustrative, instructive, and not restrictive. Those of ordinary skill in the art, as inspired by the description, may produce many forms without departing from the scope claimed by the present invention, all of which fall within the protection scope of the present invention.

What is claimed is:

1. A multi-port directional coupler, wherein
the multi-port directional coupler uses a PCB microstrip circuit and is provided with 6 ports, comprising a port 1, a port 2, a port 3A, a port 4, a port 5, and a port 6, wherein
the port 1 is an input of the multi-port directional coupler, and the port 2 is an output of the multi-port directional coupler;
the port 3A is a master coupling port with a given directivity value;
the port 4 is a master isolation port with a given directivity value for detecting a reflecting power of the port 2;
the port 5 is a slave coupling port for detecting a transmitting power of the port 1;
the port 6 is a slave isolation port for detecting the reflecting power of the port 2; and
the ports 5 and 6 are in mirror symmetry with the ports 3A and 4.

2. The multi-port directional coupler according to claim 1, wherein the multi-port directional coupler is provided with 3 layers of PCBs, the third layer is a bottom layer of PCB as a reference ground, the port 1 to the port 2 are located at a top layer of PCB, and the ports 5 and 6 and the ports 3A and 4 are located at the second layer of PCB, so as to improve insulation of a channel from the port 1 to the port 2.

3. The multi-port directional coupler according to claim 1, wherein
the port 3A improves a coupling degree by being connected to a slave directional coupler after being connected to a first attenuator; and
a peak input power of the slave directional coupler is less than 100 watts, and a coupling port is used as an output port.

4. The multi-port directional coupler according to claim 1, wherein the port 4, the port 5, or the port 6 is able to improve a signal-to-noise ratio by being connected to a slave directional coupler after being connected to a second attenuator, and a peak input power of the slave directional coupler is less than 100 watts, and a coupling port is used as an output port.

5. A radio frequency power amplifier system based on a directional coupler output, comprising
a control conditioning board, a pre-amplifier, a driving amplifier, a splitter, a radio frequency transistor amplifier, a combiner, and a dual directional coupler,
the dual directional coupler comprising a multi-port directional coupler and a slave directional coupler, wherein a peak input power of the slave directional coupler is less than 100 watts, and
the multi-port directional coupler uses a PCB microstrip circuit and is provided with 6 ports, comprising a port 1, a port 2, a port 3A, a port 4, a port 5, and a port 6, wherein
the port 1 is an input of the multi-port directional coupler, the port 2 is an output of the multi-port directional coupler, and the port 2 is connected to an antenna port;
the port 3A is a master coupling port with a given directivity value, and an attenuator is formed at the port 3A by adding a resistor for fine adjustment and is then connected to the slave directional coupler;
the port 4 is a master isolation port with a given directivity value for detecting a reflecting power of the port 2 and monitoring matching of an antenna;
the port 5 is a slave coupling port for detecting an input power of the port 1;
the port 6 is a slave isolation port for detecting the reflecting power of the port 2 and monitoring the matching of the antenna;
signals output by the ports 5 and 6 are attenuated and then sent to a spectrometer; and
the ports 5 and 6 are in mirror symmetry with the ports 3A and 4;
in the slave directional coupler, a port 3A1 is used as an input port, a coupling port is used as an output coupling port 3B, which is connected to the control conditioning board to form closed-loop correction of a radio frequency link, and the other 2 ports are connected to matched loads;
in the system, nonlinearity correction is carried out on a standard signal RF_IN1 generated by the spectrometer by using a feedback signal of the port 3B to form a signal RF_IN2;
the signal RF_IN2 is sent to the pre-amplifier for preliminary radio frequency power amplification to form a signal RF_IN3;
the signal RF_IN3 is sent to the driving amplifier for further radio frequency power amplification to form a signal RF_IN4; and
the signal RF_IN4 is sent to a power distributor for power distribution, then to the radio frequency transistor power amplifier, and then to the power combiner to be combined into a signal RF_C1, the signal RF_C1 is output to the directional coupler as a total power to generate a signal RF_C2, and the signal RF_C2 is sent to a radio frequency antenna of magnetic resonance.

6. The system according to claim 5, wherein the multi-port directional coupler is provided with 3 layers of PCBs, the third layer is a bottom layer of PCB as a reference ground, the port 1 to the port 2 are located at a top layer of PCB, and the ports 5 and 6 and the ports 3A and 4 are located at the second layer of PCB, so as to improve insulation of a channel from the port 1 to the port 2.

7. The system according to claim 5, wherein the power distributor performs equal-power and same-phase power distribution, M channels are formed by N powers of 2, each channel is sent to the radio frequency transistor power amplifier, the M radio frequency transistor power amplifiers enter the corresponding power combiners, and the power combiners perform equal-power and same-phase power combination.

8. The system according to claim 5, wherein
the radio frequency transistor power amplifier receives a channel signal distributed by the power distributor, and sends the channel signal to a Balun formed by PCB microstrip lines to form a signal with equal power and a phase difference of 180 degrees; and
an input of the transistor amplifier is matched according to impedance of an optimal input power to achieve balanced power amplification, then subjected to balanced matching output according to impedance of an optimal output power, which is consistent with impedance of an output Balun, and finally converted into a single-ended signal output by the output Balun and sent to the corresponding power combiner.

9. A radio frequency power linearization method for a magnetic resonance imaging system, comprising:
cascading a multi-port directional coupler and a slave directional coupler in two stages, wherein a peak input power of the slave directional coupler is less than 100 watts; the multi-port directional coupler uses a PCB microstrip circuit and is provided with 6 ports, comprising a port 1, a port 2, a port 3A, a port 4, a port 5, and a port 6, wherein the port 1 is an input of the multi-port directional coupler, the port 2 is an output of the multi-port directional coupler, and the port 2 is connected to an antenna port; the port 3A is a master coupling port with a given directivity value, and an attenuator is formed at the port 3A by adding a resistor for fine adjustment and is then connected to the slave directional coupler; the port 4 is a master isolation port with a given directivity value for outputting an attenuated power relative to the port 1 and a reflecting power of the port 2 and monitoring matching of an antenna; the port 5 is a slave coupling port for outputting the attenuated power relative to the port 1; the port 6 is a slave isolation port for outputting the attenuated power relative to the port 1 and the reflecting power of the port 2 and monitoring the matching of the antenna; signals output by the ports 5 and 6 are attenuated and then sent to a spectrometer; and the ports 5 and 6 are in mirror symmetry with the ports 3A and 4;
in the slave directional coupler, a port 3A1 is used as an input port, a coupling port is used as an output coupling port 3B, which is connected to the control conditioning board to form closed-loop correction of a radio frequency link, and the other 2 ports are connected to matched loads;
nonlinearity correction is carried out on a standard signal RF_IN1 generated by the spectrometer by using a signal output by the port 3B as a feedback signal of the multi-port directional coupler to form a signal RF_IN2;
the signal RF_IN2 is sent to the pre-amplifier for preliminary radio frequency power amplification to form a signal RF_IN3;
the signal RF_IN3 is sent to the driving amplifier for further radio frequency power amplification to form a signal RF_IN4; and
the signal RF_IN4 enters a power distributor for power distribution, then to the radio frequency transistor power amplifier, and then to the power combiner to be combined into a signal RF_C1, the signal RF_C1 is output to the directional coupler as a total power to generate a signal RF_C2, and the signal RF_C2 is sent to a radio frequency antenna of magnetic resonance.

10. The method according to claim 9, wherein
the nonlinearity correction adopts a linear correction method of analog negative feedback.
